(19) United States
(12) Patent Application Publication
(10) Pub. No.: US 2026/0154471 A1
(43) Pub. Date: Jun. 4, 2026

(54) CALCULATOR SYSTEM AND METHOD FOR ASSISTING ARCHITECTURE DESIGN FOR IT SYSTEM

(71) Applicant: Hitachi, Ltd., Tokyo (JP)

(72) Inventors: Nagisa MATSUMOTO, Tokyo (JP); Masayuki KAKIDA, Tokyo (JP); Masaharu UKEDA, Tokyo (JP)

(73) Assignee: Hitachi, Ltd., Tokyo (JP)

(21) Appl. No.: 19/122,855

(22) PCT Filed: Apr. 10, 2024
(86) PCT No.: PCT/JP2024/014536

§ 371 Date: Apr. 21, 2025

(30) Foreign Application Priority Data
May 12, 2023 (JP) 2023-079130

(51) Int. Cl. G06F 30/20

(52) U.S. Cl. CPC G06F 30/20

(57) ABSTRACT

A calculator system holds an element database managing an element as design information for implementing a non-functional requirement, and a history database storing an implementation history of a past non-functional requirement. The calculator system acquires information on the non-functional requirement implemented on an IT system achieved by an architecture as a base, refers to the element database to generate a plurality of combinations of the elements, and for each of the plurality of combinations of the elements, gives a priority representing the recommendation rank of each of the plurality of combinations of the elements. When the combination of the elements satisfying a constraint condition is not present, a substitute plan is generated by using the implementation history. The calculator system outputs at least one of the combination of the elements or the substitute plan sorted on the basis of the priority.

### INCORPORATION BY REFERENCE

The present application claims priority from Japanese Patent Application No. 2023-79130 filed on May 12, 2023, the content of which is hereby incorporated by reference into this application.

### TECHNICAL FIELD

The present invention relates to a system for assisting architecture design.

### BACKGROUND ART

In the development of an IT system, architecture design for the IT system has an important role in view of converting a requirement expected to the IT system by a user to the structure and the form of a computer to form the base of the IT system. In the present specification, the architecture of the IT system means information that represents the components, the connection relationship between the components, and the like of the IT system in specific forms.

For the architecture design for the IT system, wide knowledge throughout the IT system and deep knowledge about the relationships, the implementation method, and the like of the components of the architecture are required. Consequently, the architecture design for the IT system at zero base takes labor and time. For this, a cloud vendor and the like provide a reference architecture corresponding to the domain and the purpose of the IT system.

The reference architecture is created on the basis of the frequently appearing structure in the domain or the best practice at the architecture design, and is structured of general service and a minimum function for achieving the purpose of the IT system.

A designer corrects the reference architecture corresponding to the similar domain or purpose according to the user requirement of the IT system, and thus can efficiently perform the architecture design for the IT system.

The user requirement is typically classified into a functional requirement and a non-functional requirement. The functional requirement is a requirement about the function and the behavior provided by the IT system, and the non-functional requirement is a requirement about the quality of the IT system, such as performance, security, and availability. The non-functional requirement is often achieved by the combination of elements structuring the architecture, and thus, the designer is required to design the architecture so as to satisfy the user requirement in consideration of the relationship and the influence between the non-functional requirements. Therefore, also in the architecture design for the IT system using the reference architecture, wide knowledge and experience are required.

Thus, in the conventional technique, when the designer does not have the sufficient development ability, it is difficult to design the architecture of the IT system satisfying the user requirement.

### CITATION LIST

### Patent Literature

Patent Literature 1: Japanese Unexamined Patent Application Publication No. 2016-110325

### Nonpatent Literature

Nonpatent Literature 1: Information-technology Promotion Agency, Japan, “Non-functional requirement grades”, [online], April 2018, [searched on Dec. 27, 2022], Internet <URL: https://www.ipa.go.jp/sec/softwareengineering/std/ent03-b.html>

### SUMMARY OF INVENTION

### Technical Problem

The technique described in Patent Literature 1 is known to the above problems. Patent Literature 1 describes that “In a system design assistance apparatus 180, design information achieving each of a plurality of requirements related to a system to be newly designed is identified in a first table, and when after the result of the identification, a plurality of pieces of design information are identified for one of the requirements, a suitable rank for the usage of the combination of each of the plurality of pieces of design information and the design information identified for the different requirement is referred in a second table to identify the design information as the combination in which the suitable rank is higher, and the identified design information for each of the plurality of requirements is outputted to a predetermined device.”.

By using the technique described in Patent Literature 1, it is possible to output the design information satisfying the plurality of requirements and having the high suitable rank. However, Patent Literature 1 has the following problems. One problem is that the ranking that considers the cost for the case of implementing the architecture of the IT system is not performed. Another problem is that the changing reference of the substitute plan generated when there is no suitable combination of design information is not clear.

The present invention has been made in view of the problems as described above and an object of the present invention is to provide a system and a method for performing the ranking of the architecture of an IT system in consideration of a cost and for generating a substitute plan on the basis of a changing reference that can present grounds to a user when the suitable architecture cannot be generated.

### Solution to Problem

Among this disclosure, a typical one of summary is briefly described as follows. That is, a calculator system for assisting architecture design for an IT system holds an element database that stores data in which a non-functional requirement and an element as design information for implementing the non-functional requirement are associated and a history database that stores the implementation history of the past non-functional requirement, acquires information on the non-functional requirement implemented on the IT system that is achieved by an architecture as a base, refers to the element database to generate a plurality of combinations of the elements each for implementing the non-functional requirement, calculates an evaluation index used for deciding a recommendation rank for each of the plurality of combinations of the elements, gives a priority representing the recommendation rank of each of the plurality of combinations of the elements on the basis of the evaluation index, judges whether or not the combination of the elements satisfying a constraint condition is present, when the combination of the elements satisfying the constraint condition is not present, analyzes the implementation history to identify a changing method for at least one element included in the combination of the elements, corrects the combination of the elements on the basis of the identified changing method to generate a substitute plan, and outputs at least one of the combination of the elements or the substitute plan sorted on the basis of the priority.

### Advantageous Effects of Invention

According to an aspect of the present invention, the calculator system can assist the suitable architecture design for the IT system. Objects, configurations, and effects other than the above will be apparent from the description of the following embodiments.

### BRIEF DESCRIPTION OF DRAWINGS

FIG. 1 is a diagram illustrating an example of the configuration of an architecture design assistance system of a first embodiment.

FIG. 2A is a diagram illustrating an example of the data structure of an element DB of the first embodiment.

FIG. 2B is a diagram illustrating an example of the data structure of the element DB of the first embodiment.

FIG. 3A is a diagram illustrating an example of the data structure of a history DB of the first embodiment.

FIG. 3B is a diagram illustrating an example of the data structure of the history DB of the first embodiment.

FIG. 4 is a flowchart explaining an example of a process executed by the architecture design assistance system of the first embodiment.

FIG. 5 is a diagram explaining an example of a method for identifying an element for a non-functional requirement and a method for generating the combination of the elements by the architecture design assistance system of the first embodiment.

FIG. 6 is a diagram explaining an example of a cost calculation method by the architecture design assistance system of the first embodiment.

FIG. 7 is a flowchart explaining an example of a priority decision process executed by the architecture design assistance system of the first embodiment.

FIG. 8 is a flowchart explaining an example of a priority decision process executed by the architecture design assistance system of the first embodiment.

FIG. 9 is a flowchart explaining an example of a priority decision process executed by the architecture design assistance system of the first embodiment.

FIG. 10 shows diagrams illustrating a specific priority decision method of the first embodiment.

FIG. 11A is a flowchart explaining an example of a substitute plan generation process executed by the architecture design assistance system of the first embodiment.

FIG. 11B is a flowchart explaining an example of the substitute plan generation process executed by the architecture design assistance system of the first embodiment.

FIG. 12A is a flowchart explaining an example of the substitute plan generation process executed by the architecture design assistance system of the first embodiment.

FIG. 12B is a flowchart explaining an example of the substitute plan generation process executed by the architecture design assistance system of the first embodiment.

FIG. 13 is a flowchart explaining an example of a substitute plan generation process executed by the architecture design assistance system of a third embodiment.

FIG. 14 is a flowchart explaining an example of a process executed by the architecture design assistance system of the third embodiment.

FIG. 15 is a diagram illustrating an example of the configuration of the architecture design assistance system of a fourth embodiment.

### DESCRIPTION OF EMBODIMENTS

One embodiment of the present invention will now be described with reference to the drawings. However, the present invention is not construed by being limited to the descried content of the following embodiments. Those skilled in the art can easily understand that within a scope without departing from the idea or the purport of the present invention, its specific configuration can be changed.

In the configuration of the invention described below, the same or similar configurations or functions are indicated by the same reference numerals, and the overlapped description thereof is omitted.

The denotations of the “first”, “second”, “third”, and the like in the present specification and the like are given for identifying the components, and do not necessarily limit the number or the order.

### First Embodiment

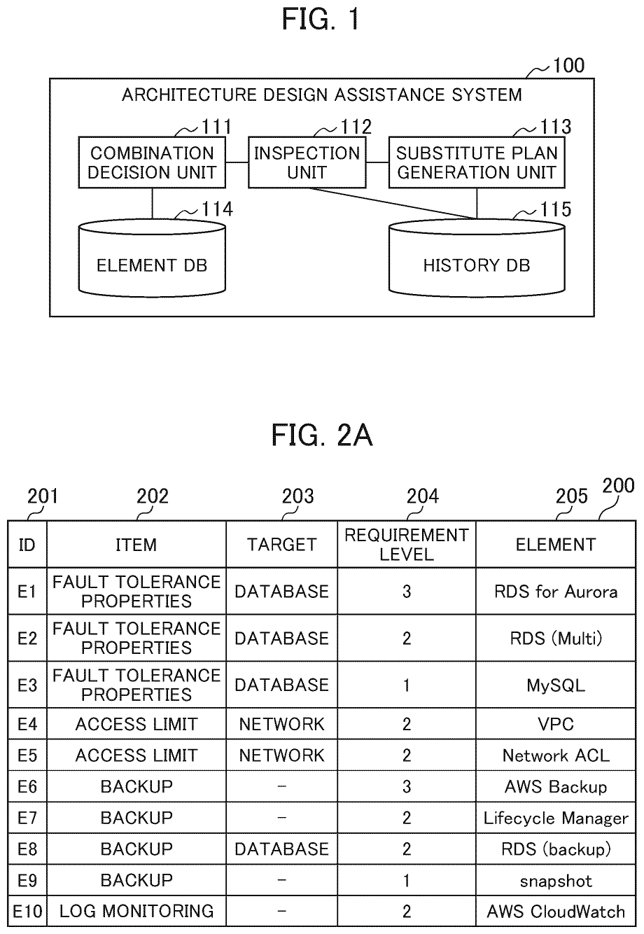

FIG. 1 is a diagram illustrating an example of the configuration of an architecture design assistance system 100 of a first embodiment.

The architecture design assistance system 100 of the first embodiment assists architecture design for an IT system. As described later, the architecture design assistance system 100 generates the architecture of the IT system achieving a non-functional requirement in consideration of cost constraint.

In the present specification, in the architecture of the IT system, it is assumed that information defining the type of service, the connection between the services, physical device connection, a parameter, and the like is information structured of an element. In addition, in the present specification, for a user, a use case adding the non-functional requirement to the reference architecture (basic structure) of the IT system provided by a cloud vendor and the like is assumed.

The architecture design assistance system 100 includes a combination decision unit 111, an inspection unit 112, and a substitute plan generation unit 113, and holds an element DB 114 and a history DB 115. The architecture design assistance system 100 may directly exchange information with the user, and may exchange information with an external system.

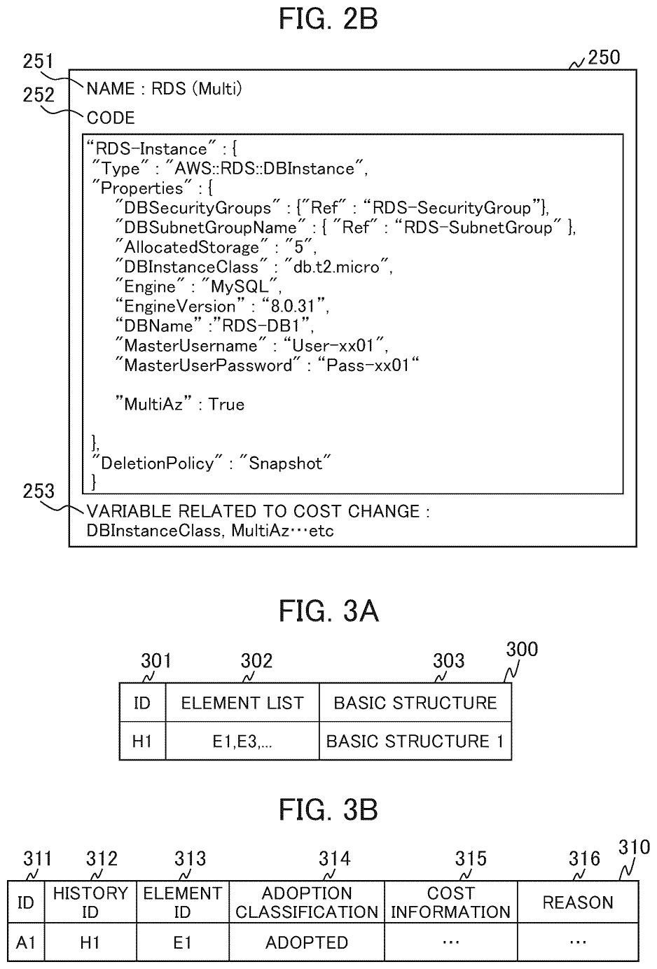

The element DB 114 is a database storing the element that is setting information for implementing the non-functional requirement. It should be noted that the element DB 114 may be held by an external server different from the architecture design assistance system 100. The details of the element DB 114 will be described with reference to FIGS. 2A and 2B.

The history DB 115 is a database storing the history of the implementation of the architecture of the IT system. The details of the history DB 115 will be described with reference to FIGS. 3A and 3B.

The combination decision unit 111 refers to the element DB 114, extracts the element for achieving the designated non-functional requirement, and decides the combination of the elements.

The inspection unit 112 calculates a cost as an evaluation index based on the viewpoint of development, implementation, operation, and the like for the combination of the elements decided by the combination decision unit 111, and decides a priority for deciding the recommendation rank (application rank) of the combination of the elements on the basis of the cost. The cost is, for example, a cost required for the introduction and the maintenance of the IT system, the number of processes required for the implementation, the management level of the service in the IT system, and the like.

The substitute plan generation unit 113 refers to the history DB 115, identifies an element changing method, and corrects the element of the combination of the elements on the basis of the identified changing method, thereby generating a substitute plan. Here, the changing of the element is a concept including the correction of the variable and the parameter of the element and the changing of the element itself.

It should be noted that the architecture design assistance system 100 is achieved by using a calculator having a processor, a memory, and a network interface.

FIGS. 2A and 2B are each a diagram illustrating an example of the data structure of the element DB 114 of the first embodiment.

The element DB 114 stores, as information for managing the element for achieving the non-functional requirement, for example, a table 200 as illustrated in FIG. 2A. In the present embodiment, the non-functional requirement is classified on the basis of the item and the target of the non-functional requirement illustrated in the non-functional requirement grades table of Nonpatent Literature 1. In addition, the requirement level is defined as a numerical value relatively representing the range of the non-functional requirement to which each element can correspond. The table 200 stores an entry including an ID 201, an item 202, a target 203, a requirement level 204, and an element 205.

For example, the element achieving the “non-functional requirement related to the fault tolerance properties at the requirement level 3 targeting the database” represents “RDS for Aurora”. It should be noted that a plurality of elements for achieving the non-functional requirements having the same item, target, and requirement level may be present, and a new field may be added to the table 200 such that the element corresponding to the information on the non-functional requirement is in one-on-one manner.

In the element 205, for example, data 250 having a data structure as illustrated in FIG. 2B is stored. The data 250 includes information necessary for achieving the non-functional requirement. For example, the data 250 includes a name 251 of a resource achieving the non-functional requirement, a code 252 representing the structure, the parameter, and the setting of the resource, a variable 253 related to the cost, and the like. It should be noted that the data 250 illustrated in FIG. 2B is only an example, and the present invention is not limited to this. For example, the detailed structure between the resources may be included as a main resource and a sub-resource, and the importance degree and the setting method of the parameter may be included.

For example, the data 250 may be described in the form of IaC (Infrastructure as Code) provided by the cloud vendor, and may be a text in itemized form.

FIGS. 3A and 3B are each a diagram illustrating an example of the data structure of the history DB 115 of the first embodiment.

The history DB 115 stores the implementation history of the non-functional requirement. For example, the history DB 115 stores a history table 300 as illustrated in FIG. 3A and an adoption/non-adoption result table 310 as illustrated in FIG. 3B. It should be noted that the history DB 115 may include a table managing the implementation state of the non-functional requirement and the like.

The history table 300 stores an entry (implementation history) for managing the element for achieving the non-functional requirement implemented on the IT system. The entry includes an ID 301, an element list 302, and a basic structure 303. The element list 302 is a field storing the list of the ID (ID 201) of the element implemented on the IT system. The basic structure 303 is a field storing the reference architecture of the IT system. It should be noted that the basic structure 303 may store the main purpose, the domain, the structure diagram, and the like of the IT system.

The element is managed by the element DB 114 in association with the non-functional requirement. Thus, it is possible to grasp, from the history table 300, which element for the non-functional requirement is implemented on the IT system. In addition, the details of the architecture of the IT system on which the element for the non-functional requirement is implemented can be grasped.

The adoption/non-adoption result table 310 stores an entry (implementation judgment history) for managing a judgment result whether or not the implementation of the element is adopted by the user. The entry includes an ID 311, a history ID 312, an element ID 313, an adoption classification 314, cost information 315, and a reason 316. The cost information 315 is a field storing information related to the cost noted in the judgment whether or not the implementation is enabled. For example, the cost classification, the judgement equation, and the like are stored. The reason 316 is a field which stores a reason why the user has not adopted the implementation of the element. The reason may be able to be selected in pull-down form, and may be freely described by the user.

From the adoption/non-adoption result table 310, the reference for judging whether or not the element is adopted can be grasped. By managing the implementation judgment history in association with the implementation history, the priority rank of the implementation of the non-functional requirement in the arbitrary IT system can be grasped.

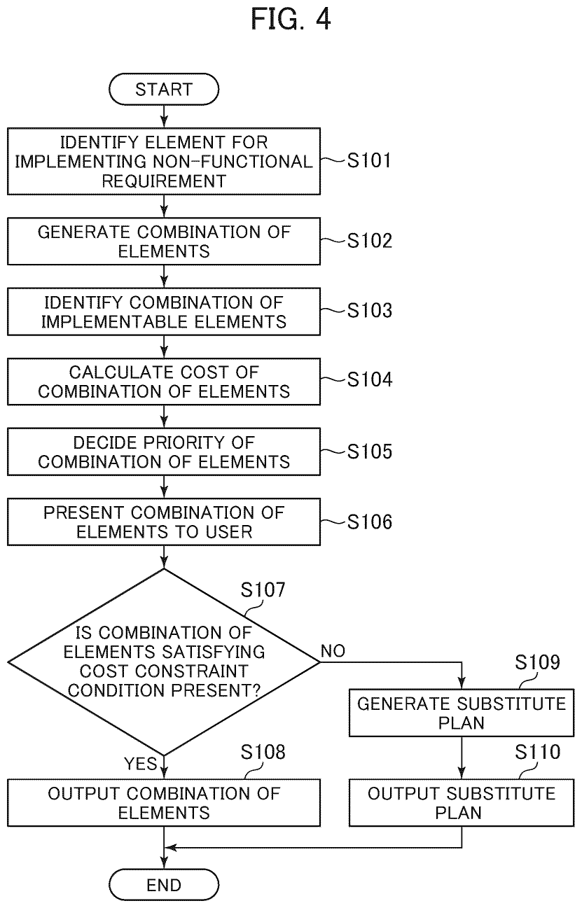

FIG. 4 is a flowchart explaining an example of a process executed by the architecture design assistance system 100 of the first embodiment.

The architecture design assistance system 100 starts the process described below when receiving a design requirement including the non-functional requirement from the user. The user should input the item and the target as information designating the non-functional requirement. It should be noted that the requirement level may be included. The requirement level may be designated by a numerical value, and may be designated by a range.

The combination decision unit 111 refers to the element DB 114, and identifies the element corresponding to the designated non-functional requirement (step S101).

The combination decision unit 111 generates the combinations of the elements of all the designated non-functional requirements (step S102).

The combination decision unit 111 confirms the aligning properties for each combination of the elements, and identifies the combination of the implementable elements (step S103).

For example, it is assumed that the element 1 and the element 2 corresponding to the non-functional requirement α and the element 3 corresponding to the non-functional requirement β are present. It should be noted that the element 1 targets the service A, and the element 2 and the element 3 target the service B. At this time, as the combinations satisfying the non-functional requirements a and B at the same time, the combination of the element 1 and the element 3 and the combination of the element 2 and the element 3 are considered. However, combining the element 1 targeting the service A and the element 3 targeting the service B is not suitable as the implementation of the IT system. Thus, the combination decision unit 111 deletes the combination of the element 1 and the element 3. It should be noted that as the information for identifying the combination of the implementable elements, the basic structure of the IT system may be used.

The inspection unit 112 calculates the cost of each combination of the elements (step S104). For example, the costs as described below are considered.

(Pattern 1) When the money amount required for the implementation is calculated as the cost, the inspection unit 112 calculates the cost on the basis of charge information presented by the cloud vendor. In addition, the cost may be calculated on the basis of the difference between the basic information before the implementation of the combination of the elements and the basic information after the implementation of the combination of the elements.

(Pattern 2) When the number of processes required for the implementation is calculated as the cost, the inspection unit 112 calculates the cost on the basis of the number of resources included in the element, the number of variables requiring definition, and the like. It should be noted that the cost can be calculated on the basis of the element or the implementation history of the element.

(Pattern 3) When the labor of the operation of the implemented IT system is calculated as the cost, the inspection unit 112 calculates the cost on the basis of the management level, the service type, and the like of the element. It should be noted that the cost can be calculated on the basis of the element or the implementation history of the element.

The inspection unit 112 calculates, as the cost of the combination of the elements, the total value, the maximum value, the minimum value, and the average value of the costs of the respective elements included in the combination of the elements. It should be noted that the cost may be calculated in consideration of the overlapped content of the element.

The inspection unit 112 decides the priority of the combination of the elements on the basis of the cost (step S105). For example, a method for setting the priority to be higher in the cost ascending order is considered.

It should be noted that when a plurality of types of costs are calculated, the priority may be decided on the basis of the total value of various costs or the arbitrary cost. In addition, the inspection unit 112 may identify the cost to be noted on the basis of the history DB 115. The details of the priority decision method will be described later.

The architecture design assistance system 100 sorts the combination of the elements on the basis of the priority, and presents the combination of the elements to the user (step S106).

The user confirms the combination of the elements, decides the cost constraint condition, and inputs a cost constraint condition to the architecture design assistance system 100. The cost constraint condition is a conditional equation related to the cost or the priority, the number of combinations of the elements selected, and the like.

When acquiring the cost constraint condition from the user, the inspection unit 112 judges whether or not the combination of the elements satisfying the cost constraint condition is present (step S107).

When the combination of the elements satisfying the cost constraint condition is present, the inspection unit 112 outputs the combination of the elements (step S108), and then, ends the process.

When the combination of the elements satisfying the cost constraint condition is not present, the substitute plan generation unit 113 generates the combination of the elements that becomes the substitute plan (step S109). The number of substitute plans may be one or plural.

For example, the substitute plan generation unit 113 identifies the element having a low implementation frequency in a certain combination of the elements on the basis of the history DB 115, and changes the requirement level and the like of the element, thereby generating the substitute plan. At this time, the substitute plan generation unit 113 calculates the cost of the substitute plan, and judges whether or not the cost constraint condition is satisfied.

The substitute plan generation unit 113 outputs the substitute plan satisfying the cost constraint condition (step S110), and then, ends the process.

It should be noted that when in step S107, the combination of the elements satisfying the cost constraint condition and the combination of the elements not satisfying the cost constraint condition are present, the substitute plan generation unit 113 may go to step S109.

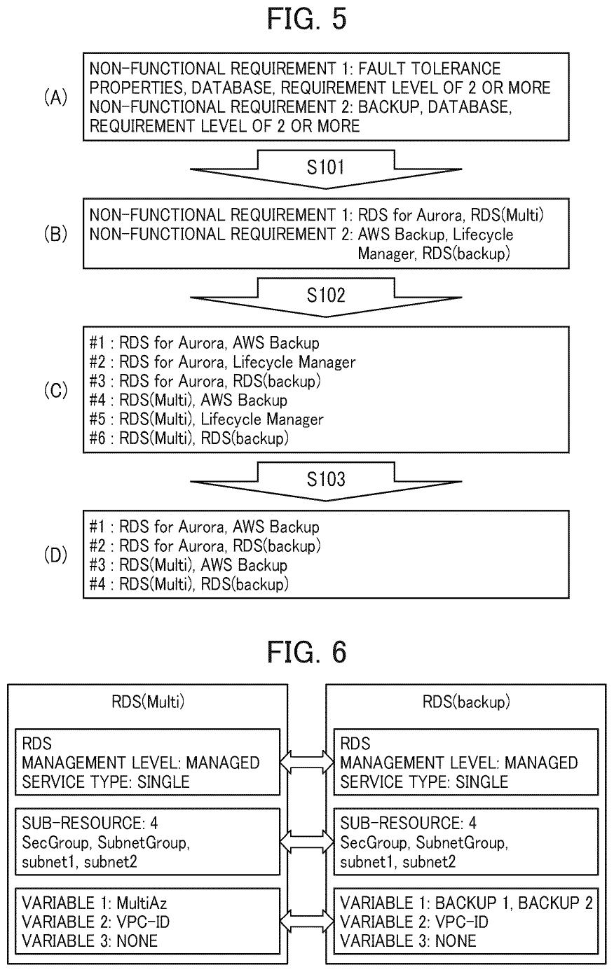

The respective processes will be specifically described with reference to FIGS. 5 to 12B.

First, the method for generating the combination of the elements will be described with reference to FIG. 5. FIG. 5 is a diagram explaining an example of the method for identifying the element for the non-functional requirement and the method for generating the combination of elements by the architecture design assistance system 100 of the first embodiment.

It is assumed that the architecture design assistance system 100 receives information designating the non-functional requirement as described below (see FIG. 5 (A)).

(Non-functional requirement 1) The item is the fault tolerance properties, the target is the database, and the requirement level is 2 or more.

(Non-functional requirement 2) The item is the backup, the target is the database, and the requirement level is 2 or more.

In step S101, as illustrated in FIG. 5(B), the combination decision unit 111 refers to the table 200 illustrated in FIG. 2A, and identifies, as the elements for achieving the non-functional requirement 1, the “RDS for Aurora” and the “RDS (Multi)”, and identifies, as the elements for achieving the non-functional requirement 2, the “AWS Backup”, the “Lifecycle Manager”, and the “RDS (backup)”.

In step S102, as illustrated in FIG. 5(C), the combination decision unit 111 generates six combinations of the elements.

The target of the “RDS for Aurora” and the “RDS (Multi)” is the RDS, but the target of the “Lifecycle Manager” is the EC2, so that the targets are different. Thus, the elements cannot be implemented at the same time as the elements applied to the same database. Therefore, in step S103, as illustrated in FIG. 5(D), the combination decision unit 111 deletes the combinations of the elements including the “RDS for Aurora, Lifecycle Manager” and the “RDS (Multi), Lifecycle Manager”, and outputs four combinations of the elements.

Next, the cost calculation method will be described with reference to FIG. 6. FIG. 6 is a diagram explaining an example of the cost calculation method by the architecture design assistance system 100 of the first embodiment.

Here, the cost calculation method for the combination of the elements “RDS (Multi), RDS (backup)” will be described.

First, the money cost calculation method will be described. In the present embodiment, it is assumed that the money cost calculation method is previously set to the element. For example, for the element RDS (Multi), the calculation method as expressed in Equation (1) is set, and for the element RDS (backup), the calculation method as expressed in Equation (2) is set.

$$\begin{matrix}[ Mathematical Equation 1 ] & \\ ( DB instance time charge on an as - used basis + storage time charge on an as - used basis ) \times 2 & ( 1 )\end{matrix}$$

$$\begin{matrix}[ Mathematical Equation 2 ] & \\ Backup storage amount & ( 2 )\end{matrix}$$

Since the variables of the above cost calculation equations are different, the inspection unit 112 calculates, as the money cost, the sum of the values obtained from each of Equation (1) and Equation (2).

Next, the implementation/operation cost calculation method will be described. The inspection unit 112 can acquire information as illustrated in FIG. 6 from the element RDS (Multi) and the element RDS (backup). It is found that in the inspection unit 112, both of the two elements have the same feature, the management level is the managed, the service type is single, and the number of sub-resources is 4. In addition, it is found that the element RDS (Multi) includes two variables by totaling the variable 1 and the variable 2 as the variables necessary for the implementation, and the element RDS (backup) includes three variables by totaling the variable 1 and the variable 2 as the variables necessary for the implementation.

The inspection unit 112 compares the information acquired from the element with the information acquired from the different element, and calculates the cost for the case where the element and the different element are implemented at the same time. For example, the inspection unit 112 calculates, as the implementation/operation cost, the management level, the service type, the number of structures, and the number of variables. In the example illustrated in FIG. 6, the service type is single, the number of variables 1 is 3, the number of variables 2 is 1 since the variables are shared between the elements, and the number of variables 3 is 0. The number of sub-resources is 4 since the sub-resources are shared between the structures, and the number of structures is 5 by the addition of RDS as the shared main resource to this. In addition, the inspection unit 112 converts, to the cost, the combination of the management levels in the combination of the elements. For example, when the management levels of all the elements are the self-managed, the cost is small, and when the self-managed and the managed are mixed, the cost is intermediate, and when the management levels of all the elements are the managed, the cost is large.

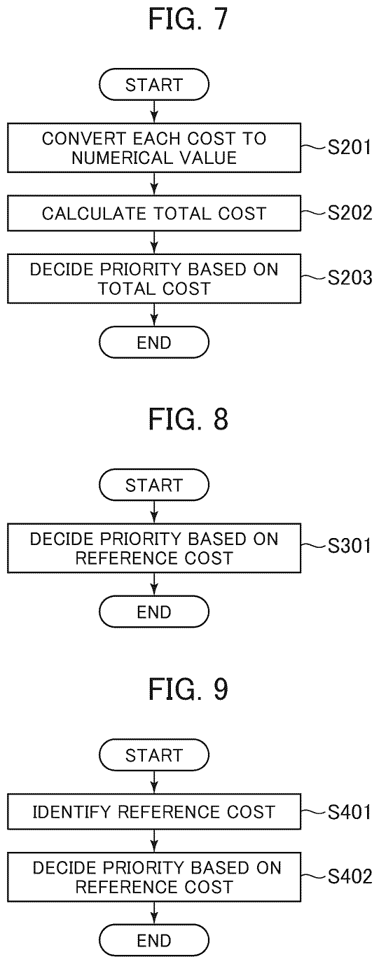

Next, the priority decision method will be described with reference to FIGS. 7 to 10(B).

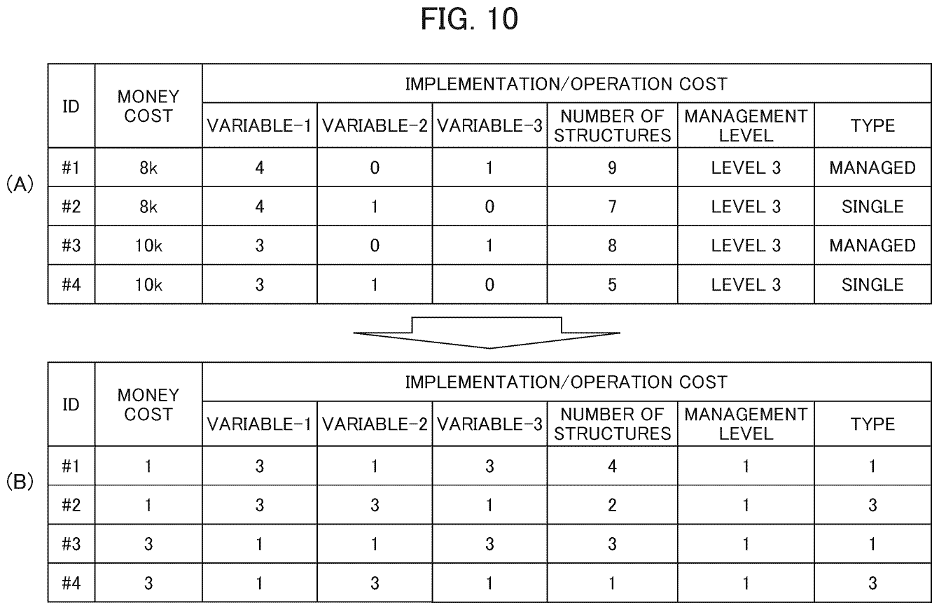

FIGS. 7, 8, and 9 are each a flowchart explaining an example of the priority decision process executed by the architecture design assistance system 100 of the first embodiment. FIG. 10 shows diagrams illustrating the specific priority decision method of the first embodiment.

First, the priority decision process of FIG. 7 will be described. For each combination of the elements, the inspection unit 112 converts the money cost to a numerical value representing a rank, and also converts the implementation/operation cost to a numerical value representing a rank (step S201). The numerical value conversion method is previously set. For example, the inspection unit 112 outputs the smaller numerical value in cost ascending order.

For example, when for each combination of the elements illustrated in FIG. 5, the cost as described in FIG. 10(A) is calculated, the inspection unit 112 converts the cost to a numerical value as illustrated in FIG. 10(B).

For each combination of the elements, the inspection unit 112 calculates the total cost on the basis of the numerical values calculated from the respective costs (step S202).

For example, the inspection unit 112 calculates, as the total cost, the total value of the numerical values calculated from the respective costs. In addition, the total cost may be calculated from the weighted sum of the numerical values.

The inspection unit 112 decides the priority of the combination of the elements on the basis of the total cost (step S203).

For example, the priority is given such that the combination of the elements having the small total cost is displayed on a priority basis. It should be noted that the same priority may be given for the combinations of the elements in which the total cost is the same, and the unique priority may be given on the basis of the comparison result of the individual costs.

When the total value of the numerical values of the respective costs is the total cost, in the decision method of FIG. 7, the high priority is given to the combinations of the elements in which the IDs of FIG. 5(D) are 3, 4, and the low priority is given to the combinations of the elements in which the IDs of FIG. 5(D) are 1, 2. The combination of the elements to which the high priority is given is presented to the user on a priority basis.

Next, the priority decision method of FIG. 8 will be described. The inspection unit 112 decides the priority of the combination of the elements on the basis of the reference cost of each combination of the elements (step S301). It should be noted that for the combinations of the elements in which the reference cost is the same, the same priority may be given, and the unique priority may be given on the basis of the comparison result of other costs.

The reference cost is a cost used for deciding the priority, may be previously set, and may be able to be selected by the user. It should be noted that the number of reference costs may be plural.

When the number of the structures is the reference cost, the high priority is given in the order of the element in which the ID of FIG. 5(D) is 4, the element in which the ID of FIG. 5(D) is 2, the element in which the ID of FIG. 5(D) is 3, and the element in which the ID of FIG. 5(D) is 1.

Next, the priority decision method of FIG. 9 will be described. The inspection unit 112 refers to the adoption/non-adoption result table 310, and identifies the reference cost (step S401).

For example, the inspection unit 112 calculates the usage frequencies of various costs on the basis of the cost information 315 of each entry of the adoption/non-adoption result table 310. The inspection unit 112 identifies, as the reference cost, the cost of the classification in which the usage frequency is the highest.

It should be noted that the usage frequency may be calculated by using only the entry in which the element or the basic structure is similar. It should be noted that the number of reference costs may be plural.

The inspection unit 112 decides the priority of the combination of the elements on the basis of the reference cost of each combination of the elements (step S402). It should be noted that for the combinations of the elements in which the reference cost is the same, the same priority may be given, and the unique priority may be given on the basis of the comparison result of other costs.

When the service type is identified as the reference cost, the high priority is given to the combinations of elements in which the IDs of FIG. 5(D) are 1, 3, and the low priority is given to the combinations of elements in which the IDs of FIG. 5(D) are 2, 4.

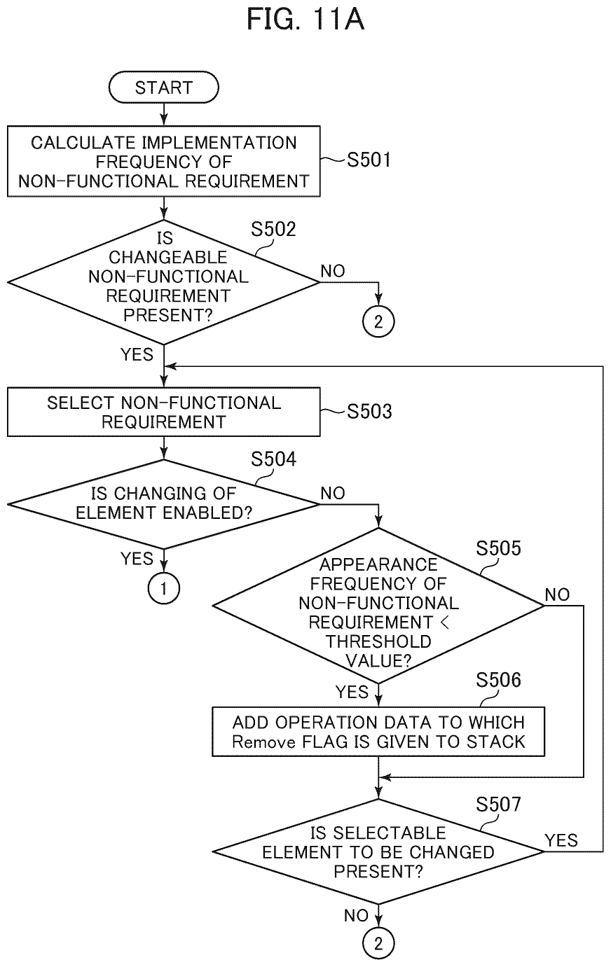

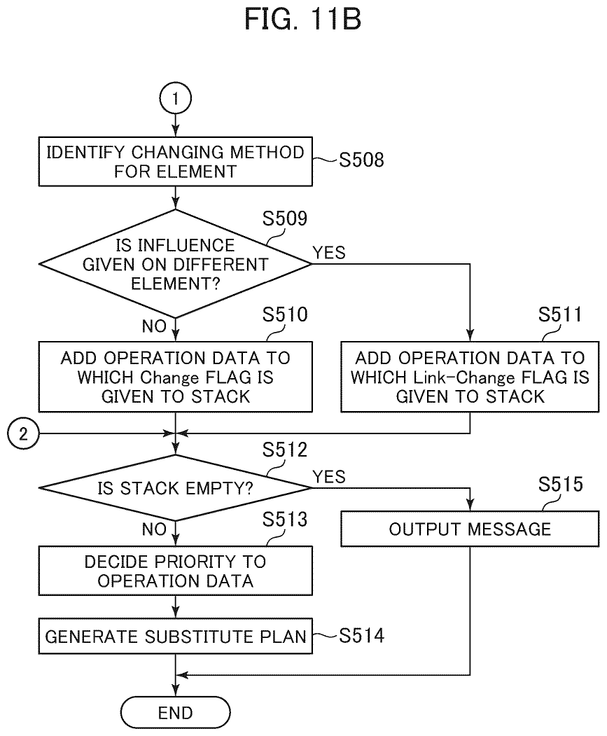

Next, the substitute plan generation method will be described with reference to FIGS. 11A to 14.

When the combination of the elements satisfying the cost constraint condition is not present, some elements in the combination are changed, so that the combination of the elements satisfying the cost constraint condition can be generated. However, the changing of the non-functional requirement requires knowledge and experience. The architecture design assistance system 100 of the first embodiment identifies the element changing method by using the implementation history of the past non-functional requirement, and generates the substitute plan.

FIGS. 11A and 11B are each a flowchart explaining an example of the substitute plan generation process executed by the architecture design assistance system 100 of the first embodiment.

In the substitute plan generation method illustrated in FIGS. 11A and 11B, the changing of the element is performed on the basis of the implementation frequency. First, the substitute plan generation unit 113 selects the combination of the elements as the base on the basis of the priority of the combination of the elements outputted by the inspection unit 112. The number of combinations of the elements as the base may be one, and may be plural. Here, it is assumed that one combination of the elements as the base is selected. When a plurality of combinations of the elements as the base are selected, the process described below will be executed to each combination of the elements.

The substitute plan generation unit 113 refers to the history table 300, and calculates the implementation frequency of each non-functional requirement corresponding to the combination of the elements as the base (step S501). Here, the implementation frequency of the non-functional requirement represents the number of times in which the element for achieving the non-functional requirement is implemented.

Specifically, the substitute plan generation unit 113 identifies the element for achieving the non-functional requirement. The substitute plan generation unit 113 calculates, as the implementation frequency of the non-functional requirement, the number of entries in which the ID of the identified element is stored in the element list 302.

It should be noted that only the entry in which the basic structure is similar may be to be searched. In addition, the user may designate the non-functional requirement which calculates the execution frequency.

On the basis of the implementation frequency of each non-functional requirement, the substitute plan generation unit 113 judges whether or not the changeable non-functional requirement is present (step S502).

Specifically, the substitute plan generation unit 113 calculates the implementation frequency difference between the non-functional requirements corresponding to the combinations of the elements as the base. When the difference is present in the implementation frequencies between the non-functional requirements, the substitute plan generation unit 113 judges that the changeable non-functional requirement is present.

When the changeable non-functional requirement is not present, the substitute plan generation unit 113 goes to step S512.

When the changeable non-functional requirement is present, the substitute plan generation unit 113 selects the non-functional requirement to be changed (step S503). Here, it is assumed that the non-functional requirement is selected in implementation frequency ascending order. That is, the non-functional requirement in which implementation achievement is low is selected as the non-functional requirement to be changed.

The substitute plan generation unit 113 judges whether or not the element corresponding to the selected non-functional requirement is changeable (step S504).

For example, when the cost is not changed with the correction of the variable or the parameter of the element, or when the cost is not changed even if the element is changed to the different element having the same level as the current non-functional requirement or the different element in which the level is different, it is judged that the selected element is not changeable. This is because even if the changing of the element is performed, the cost constraint condition is not satisfied.

When the element corresponding to the selected non-functional requirement is not changeable, the substitute plan generation unit 113 judges whether or not the implementation frequency of the non-frequency requirement is less than the predetermined threshold value (step S505). This judges whether or not the non-functional requirement is the non-functional requirement having few opportunities to be implemented on the architecture of the IT system.

When the implementation frequency of the non-functional requirement is the predetermined threshold value or more, the substitute plan generation unit 113 goes to step S507.

When the implementation frequency of the non-functional requirement is less than the predetermined threshold value, the substitute plan generation unit 113 gives the Remove flag to the operation data including the element corresponding to the non-functional requirement, and adds the resultant operation data to the substitute plan candidate stack (step S506). Thereafter, the substitute plan generation unit 113 goes to step S507. The Remove flag is a flag representing the deletion operation of the element.

In step S507, the substitute plan generation unit 113 judges whether or not the selectable element to be changed is present (step S507).

When the selectable element to be changed is not present, the substitute plan generation unit 113 goes to step S512.

When the selectable element to be changed is present, the substitute plan generation unit 113 returns to step S503.

It should be noted that the processes in step S505 and step S506 may not be executed. When the judgment result in step S504 is NO, the substitute plan generation unit 113 goes to step S507.

In step S504, when the element corresponding to the selected non-functional requirement is changeable, the substitute plan generation unit 113 identifies the changing method for the element (step S508).

Specifically, the substitute plan generation unit 113 extracts the changing method by which the cost is changed. The changing method includes the correction of the variable or the parameter of the element or the changing of the element. When a plurality of changing methods are extracted, the substitute plan generation unit 113 may select one changing method or the arbitrary number of changing methods.

It should be noted that the substitute plan generation unit 113 may refer to the implementation history of the selected non-functional requirement, compare the current element with the element of the implementation history, and identify the changing method.

The substitute plan generation unit 113 judges whether or not the influence is given on the different element with the changing of the element by the identified changing method (step S509).

With the changing of the element, as described in step S103, for example, the influence in which the changed element cannot coexist with the different element is present. Thus, the presence or absence of the influence is confirmed. For example, the substitute plan generation unit 113 performs the changing of the element according to the identified changing method, compares the changed element with the different element, and judges whether or not the different element is also required to be changed. It should be noted that the presence or absence of the influence on the basic structure may be considered.

When the influence is not given on the different element with the changing of the element, the substitute plan generation unit 113 gives the Change flag to the operation data in which the current element and the changing method are associated, and adds the resultant operation data to the substitute plan candidate stack (step S510). Thereafter, the substitute plan generation unit 113 goes to step S512. The Change flag is a flag representing the performing of the changing of the element to be changed.

When the influence is given on the different element with the performing of the changing of the element, the substitute plan generation unit 113 identifies the changing method for the different element, gives the Link-Change flag to the operation data in which the current element, the different element, and the changing method are associated, and adds the resultant operation data to the substitute plan candidate stack (step S511). Thereafter, the substitute plan generation unit 113 goes to step S512. The Link-Change flag is a flag representing the performing of the changing of the element to be changed and the different element receiving the influence.

It should be noted that when the changing method for the different method is not present, the substitute plan generation unit 113 goes to step S512. In addition, the process in step S511 may be omitted. When step S509 is YES, the substitute plan generation unit 113 goes to step S512.

In step S512, the substitute plan generation unit 113 judges whether or not the substitute plan candidate stack is empty (step S512).

When the substitute plan candidate stack is not empty, the substitute plan generation unit 113 decides the priority of the operation data stored in the substitute plan candidate stack (step S513).

Specifically, the high priority is given to the operation data achieving the combination of the elements satisfying the cost constraint condition and satisfying the non-functional requirement. For giving the priority, the difference in the cost with the changing, the level of the requirement, the degree of the influence on the different element, and the like are considered. It should be noted that the number of factors for deciding the priority may be one or plural.

The substitute plan generation unit 113 generates the substitute plan on the basis of the operation data to which the priority is given and the combination of the elements as the base (step S514). Thereafter, the substitute plan generation unit 113 ends the process.

For example, the substitute plan generation unit 113 generates the substitute plan by performing the changing of the element included in the combination of the elements as the base on the basis of the operation data in which the priority is the highest. It should be noted that the substitute plan generation unit 113 may select a plurality of high-order operation data on the basis of the priority, and combine the plurality of selected operation data to generate the substitute plan.

When the substitute plan candidate stack is empty, the substitute plan generation unit 113 outputs the message notifying that the substitute plan cannot be generated (step S515). Thereafter, the substitute plan generation unit 113 ends the process.

It should be noted that the substitute plan generation unit 113 may output the message suggesting the possibility that the substitute plan can be generated, by the addition of information related to the basic structure, the changing of the selection condition of the non-functional requirement to be changed, or the like. In addition, the substitute plan generation unit 113 may refer to the implementation history to output the message suggesting the possibility that the substitute plan can be generated.

Here, the specific substitute plan generation will be described.

(Case 1) It is assumed to find that the combination of the elements in which the ID of FIG. 5(D) is 3 is the base, and in step S503, the “non-functional requirement 1” is selected, and in step S504, for the element “RDS (Multi)”, the money cost is lowered by lowering the requirement level. In step S508, the substitute plan generation unit 113 identifies the changing method for changing the element to the “MySQL-MultiAz”. The changing method does not give the influence on the different element “AWS Backup” of the combination of the elements as the base. Thus, in step S510, the substitute plan generation unit 113 gives the Change flag to the operation data in which the element “RDS (Multi)” and the above changing method are associated, and adds the resultant operation data to the substitute plan candidate stack.

(Case 2) It is assumed to find that the combination of the elements in which the ID of FIG. 5(D) is 4 is the base, and in step S503, the “non-functional requirement 1” is selected, and in step S504, for the element “RDS (Multi)”, the money cost is lowered by lowering the requirement level. In step S508, the substitute plan generation unit 113 identifies the changing method for changing the element to the “MySQL-MultiAz”. Since the changing method gives the influence on the different element “RDS (backup)” of the combination of the elements as the base, the changing is required for the element “RDS (backup)”. Here, it is assumed that the changing method for changing the element “RDS (backup)” to the “Lifecycle Manager” is identified. In this case, in step S510, the substitute plan generation unit 113 gives the Link-Change flag to the operation data in which the element “RDS (Multi)”, the element “RDS (backup)”, and the above changing method are associated, and adds the resultant operation data to the substitute plan candidate stack.

When the priority is given on the basis of the requirement level, the high priority is given to the operation data of the case 1, and the low priority is given to the operation data of the case 2.

Here, an example of the substitute plan generation method for the case where the constraint condition based on the implementation/operation cost is not satisfied will be described. It is assumed that the combination of the elements in which the ID of FIG. 5(D) is 1 is the base, and in step S503, the “non-functional requirement 1” is selected. To lower the operation cost of the element “RDS for Aurora”, the requirement level or the management level is required to be increased. Here, it is assumed to find that the implementation/operation cost is lowered by changing the element to the “Aurora Serverless”. In step S508, the substitute plan generation unit 113 identifies the changing method for changing the element to the “Aurora Serverless”. The changing method does not give the influence on the different element “AWS Backup” of the combination of the elements as the base. Thus, in step S510, the substitute plan generation unit 113 gives the Change flag to the operation data in which the element “RDS for Aurora” and the above changing method are associated, and adds the resultant operation data to the substitute plan candidate stack.

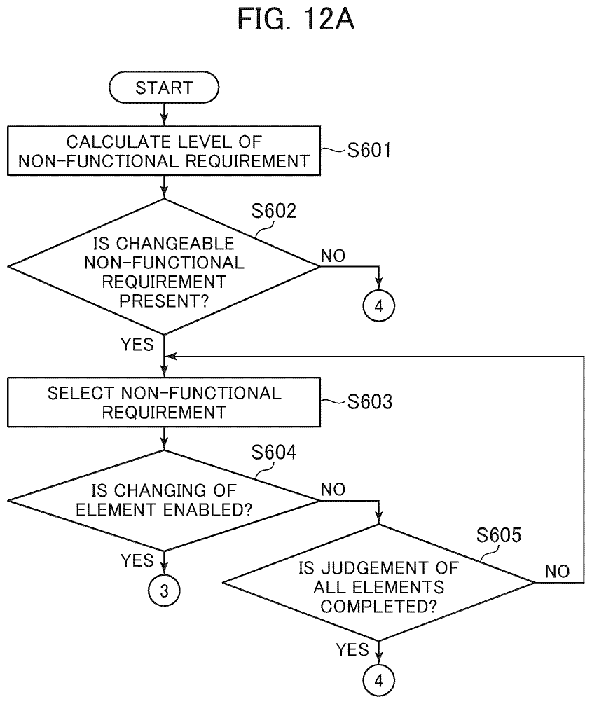

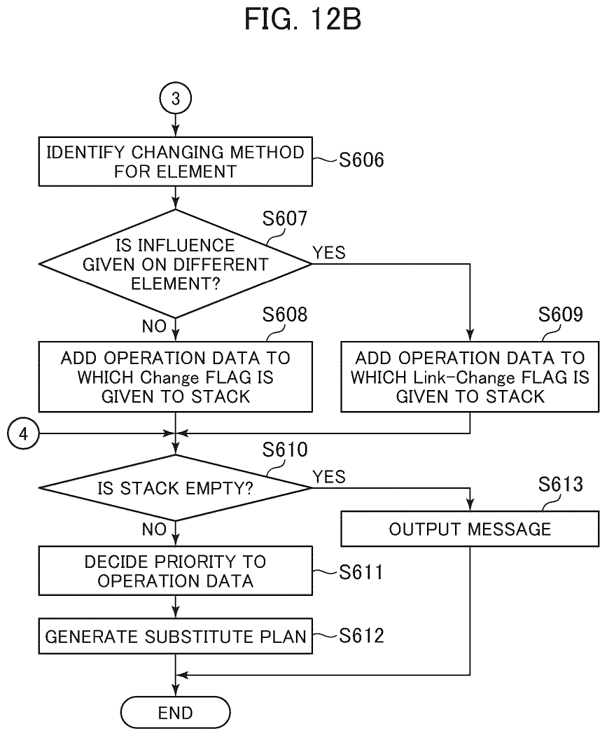

FIGS. 12A and 12B are each a flowchart explaining an example of the substitute plan generation process executed by the architecture design assistance system 100 of the first embodiment.

In the substitute plan generation method illustrated in FIGS. 12A and 12B, the changing of the element is performed on the basis of the level of the non-functional requirement. First, the substitute plan generation unit 113 selects the combination of the elements as the base on the basis of the priority of the combination of the elements outputted by the inspection unit 112. The number of combinations of the elements as the base may be one, and may be plural. Here, it is assumed that one combination of the elements as the base is selected. When the combination of the elements as the base is selected, the process described below is executed to each combination of the elements.

The substitute plan generation unit 113 refers to the history table 300, and calculates the level for the case where the non-functional requirement corresponding to the combination of the elements as the base is implemented in the past (step S601). Here, the level of the non-functional requirement is the requirement level or the management level.

Specifically, the substitute plan generation unit 113 refers to the history table 300, and acquires the level of each component. The substitute plan generation unit 113 refers to the element DB 114, and calculates the level of the non-functional requirement by using the level of the element which achieves the same non-functional requirement. The level of the non-functional requirement may be the level that appears most frequently, and may be the range of the level.

It should be noted that only the entry in which the basic structure is similar may be to be searched. In addition, the user may designate the non-functional requirement calculating the execution level.

On the basis of the level of each non-functional requirement, the substitute plan generation unit 113 judges whether or not the changeable non-functional requirement is present (step S602).

Specifically, the substitute plan generation unit 113 judges whether or not the level of the non-functional requirement designated by the user is different from the calculated level of the non-functional requirement. When the two levels are different, it is judged that the non-functional requirement is the changeable non-functional requirement.

For example, when the substitute plan which satisfies the cost constraint condition related to the money cost is generated, when the level designated by the user is higher than the calculated level, the money cost can be reduced by changing the level. Thus, the non-functional requirement in which the level difference as described above is present becomes the changeable non-functional requirement.

For example, when the substitute plan satisfying the cost constraint condition related to the implementation/operation cost is generated, when the level designated by the user is lower than the calculated level, the implementation/operation cost can be reduced by changing the level. Thus, the non-functional requirement in which the level difference as described above is present becomes the changeable non-functional requirement.

When the changeable non-functional requirement is not present, the substitute plan generation unit 113 goes to step S610.

When the changeable non-functional requirement is present, the substitute plan generation unit 113 selects the non-functional requirement to be changed (step S603). Here, it is assumed that the non-functional requirement is selected in level difference descending order. That is, the non-functional requirement in which the level of the non-functional requirement designated by the user is excessive or insufficient as compared with the past implementation history is selected as the non-functional requirement to be changed.

The substitute plan generation unit 113 judges whether or not the element corresponding to the selected non-functional requirement is changeable (step S604).

For example, when the cost is not changed with the correction of the variable or the parameter of the element, or when the cost is not changed with the changing to the different element having the same level as the current non-functional requirement or the different element in which the level is different, the substitute plan generation unit 113 judges that the selected element is not changeable. This is because even if the changing of the element is performed, the cost constraint condition is not satisfied.

When the element corresponding to the selected non-functional requirement is not changeable, the substitute plan generation unit 113 judges whether or not the judgement of all the elements to be changed is completed (step S605).

When the judgement of all the elements to be changed is not completed, the substitute plan generation unit 113 returns to step S603.

When the judgement of all the elements to be changed is completed, the substitute plan generation unit 113 goes to step S610.

In step S604, when the element corresponding to the selected non-functional requirement is changeable, the substitute plan generation unit 113 identifies the changing method for the element (step S606). The process in step S606 is the same as the process in step S508.

The substitute plan generation unit 113 judges whether or not the influence is given on the different element with the changing of the element by the identified changing method (step S607). The process in step S607 is the same as the process in step S509.

When the influence is not given on the different element with the changing of the element, the substitute plan generation unit 113 gives the Change flag to the operation data in which the current element and the changing method are associated, and adds the resultant operation data to the substitute plan candidate stack (step S608). Thereafter, the substitute plan generation unit 113 goes to step S610. The process in step S608 is the same as the process in step S510.

When the influence is given on the different element with the changing of the element, the substitute plan generation unit 113 identifies the changing method for the different element, gives the Link-Change flag to the operation data in which the current element, the different element, and the changing method are associated, and adds the resultant operation data to the substitute plan candidate stack (step S609). Thereafter, the substitute plan generation unit 113 goes to step S610. The process in step S609 is the same as the process in step S511.

In step S610, the substitute plan generation unit 113 judges whether or not the substitute plan candidate stack is empty (step S610). The process in step S610 is the same as the process in step S512.

When the substitute plan candidate stack is not empty, the substitute plan generation unit 113 decides the priority of the operation data stored in the substitute plan candidate stack (step S611). The process in step S611 is the same as the process in step S513.

The substitute plan generation unit 113 generates the substitute plan on the basis of the operation data to which the priority is given and the combination of the elements as the base (step S612). Thereafter, the substitute plan generation unit 113 ends the process. The process in step S612 is the same as the process in step S514.

In step S610, when the substitute plan candidate stack is empty, the substitute plan generation unit 113 outputs the message notifying that the substitute plan cannot be generated (step S613). Thereafter, the substitute plan generation unit 113 ends the process. The process in step S613 is the same as the process in step S515.

Here, the specific substitute plan generation will be described.

(Case 1) It is assumed that the combination of the elements in which the ID of FIG. 5(D) is 3 is the base, and in step S603, the “non-functional requirement 2” is selected. In step S604, when the element is changed to the “AWS Backup”, the combination of the elements after the changing is the same as the combination of the elements in which the ID of FIG. 5(D) is 4. Thus, the judgment result in step S604 is NO.

(Case 2) It is assumed that the combination of the elements in which the ID of FIG. 5(D) is 4 is the base, and in step S603, the “non-functional requirement 2” is selected. In step S604, it is assumed to find that the money cost is lowered by correcting the parameter of the element “RDS (backup)”. In step S606, the substitute plan generation unit 113 identifies the changing method for correcting the parameter of the element “RDS (backup)”. The correction of the parameter of the element “RDS (backup)” does not give the influence on the different element. Thus, the substitute plan generation unit 113 gives the Change flag to the operation data in which the element “RDS (backup)” and the above changing method are associated, and adds the resultant operation data to the substitute plan candidate stack.

The architecture design assistance system 100 of the first embodiment decides the recommendation rank of the combination of the elements on the basis of the cost, and presents the recommendation rank to the user. In addition, the architecture design assistance system 100 of the first embodiment generates the substitute plan on the basis of the history when the combination of the elements satisfying the cost constraint condition is not present. With this, the change and the decision of the architecture design can be efficiently assisted. Since the changing of the element is identified on the basis of the history, the history can be presented as data that becomes grounds.

### Second Embodiment

The configuration of the architecture design assistance system 100 of a second embodiment is the same as the first embodiment. The architecture design assistance system 100 of the second embodiment receives the input of the cost constraint condition together with the non-functional requirement. In this case, in the architecture design assistance system 100, the process in step S106 is omitted. Other processes are the same as the first embodiment.

By previously receiving the cost constraint condition, the inspection of the combination of the elements and the cost constraint condition can be automatically executed.

The architecture design assistance system 100 of the second embodiment can obtain the same effect as the first embodiment. Further, the architecture design assistance system 100 of the second embodiment can immediately perform the inspection of the cost constraint condition and the generation of the substitute plan.

### Third Embodiment

A third embodiment is different from the first embodiment in that the combination of the elements satisfying the implementation constraint condition is presented. Hereinbelow, the third embodiment will be described by focusing on the difference from the first embodiment.

The configuration of the architecture design assistance system 100 of the third embodiment is the same as the first embodiment. The process executed by the architecture design assistance system 100 of the third embodiment is different in part from the first embodiment.

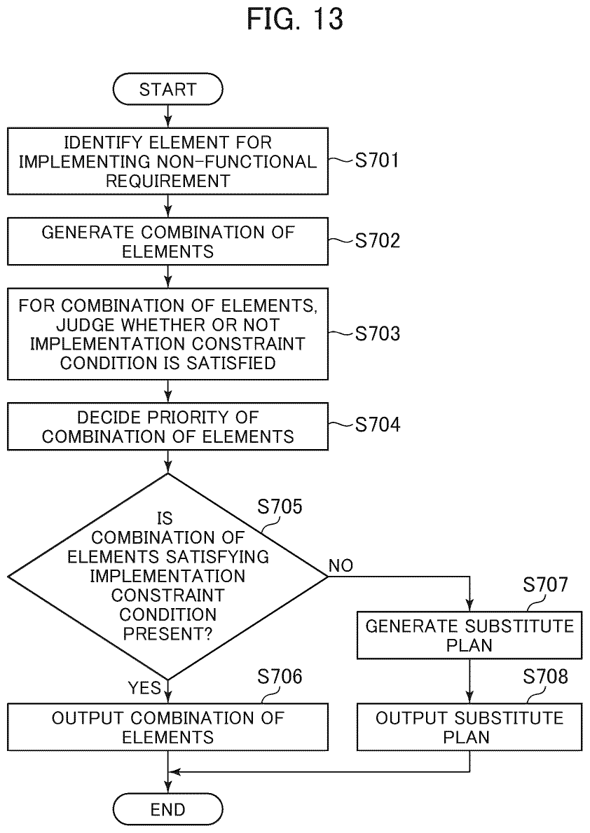

FIG. 13 is a flowchart explaining an example of the process executed by the architecture design assistance system 100 of the third embodiment.

The architecture design assistance system 100 starts the process described below when receiving a design requirement including the non-functional requirement from the user.

The combination decision unit 111 refers to the element DB 114, and identifies the element corresponding to the designated non-functional requirement (step S701). The process in step S701 is the same as the process in step S101.

The combination decision unit 111 generates the combinations of the elements for all the designated non-functional requirements (step S702). The process in step S702 is the same as the process in step S102.

For each combination of the elements, the inspection unit 112 judges whether or not the implementation constraint condition is satisfied (step S703).

The implementation constraint condition is the constraint condition related to the relationship of the non-functional requirement, the constraint condition related to the parameter and the structure information of the element, and the like. For example, the implementation constraint condition is the condition related to the magnitude relationship of the requirement level of the non-functional requirement and the like. It should be noted that the constraint condition related to the basic structure may be included.

In addition, the implementation constraint condition may be the constraint condition related to a data storing place and the like. When the constraint condition is set, it is judged that the combination of the elements including the RDS (Multi) does not satisfy the implementation constraint condition.

The inspection unit 112 decides the priority of the combination of the elements on the basis of the judgment result (step S704).

For example, the inspection unit 112 gives the high priority to the combination of the elements satisfying the implementation constraint condition, and gives the low priority to the combination of the elements not satisfying the implementation constraint condition.

The inspection unit 112 judges whether or not the combination of the elements satisfying the implementation constraint condition is present (step S705).

When the combination of the elements satisfying the implementation constraint condition is present, the inspection unit 112 outputs the combination of the elements (step S706), and thereafter, ends the process.

When the combination of the elements satisfying the implementation constraint condition is not present, the substitute plan generation unit 113 generates the substitute plan (step S707).

The substitute plan generation unit 113 outputs the substitute plan (step S708), and thereafter, ends the process.

It should be noted that when in step S705, the combination of the elements satisfying the implementation constraint condition and the element not satisfying the implementation constraint condition are present, the inspection unit 112 may go to step S707.

It should be noted that the architecture design assistance system 100 may present the judgement result in step S703 to the user. At this time, the portion not satisfying the implementation constraint condition and the like may be presented. In addition, the possibility that the implementation constraint condition is satisfied by the changing of the element may be presented.

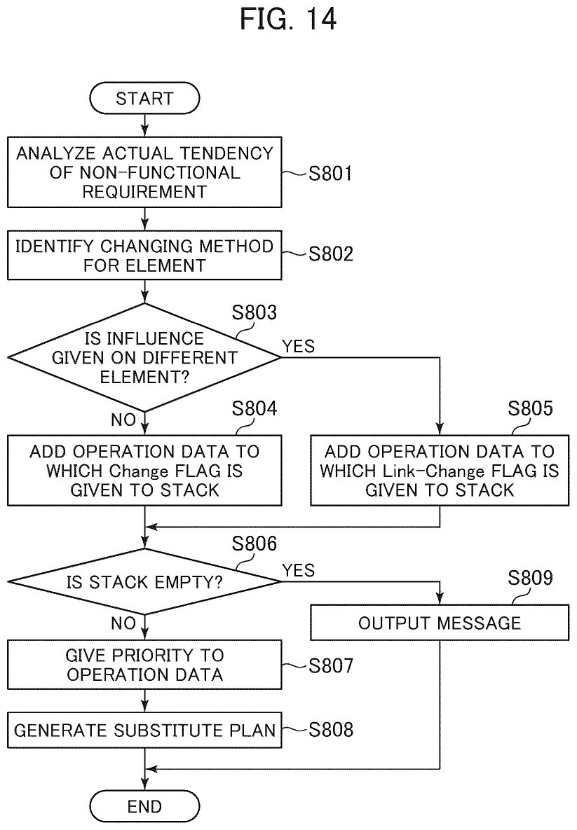

FIG. 14 is a flowchart explaining an example of the substitute plan generation process executed by the architecture design assistance system 100 of the third embodiment.

The process described below is executed to the combination of the elements not satisfying the implementation constraint condition.

The substitute plan generation unit 113 refers to the history table 300, and for the element not satisfying implementation constraint condition, analyzes the implementation tendency of the non-functional requirement corresponding to the element not satisfying the implementation constraint condition (step S801). The implementation tendency of the non-functional requirement is, for example, the element adopted or the requirement level adopted.

It should be noted that the implementation constraint condition related to the relationships of a plurality of non-functional requirements is not satisfied, the substitute plan generation unit 113 may analyze the implementation tendency of one non-functional requirement, and may analyze the implementation tendencies of a plurality of non-functional requirements. It should be noted that when the implementation tendency is not clear, the substitute plan generation unit 113 goes to step S806.

The substitute plan generation unit 113 identifies the changing method on the basis of the analyzing result (step S802). For example, the changing method by which the requirement level of the non-functional requirement is made to be the same as the past requirement level is considered.

The process from step S803 to step S809 is the same as the process from step S509 to step S515.

Here, the specific substitute plan generation will be described.

It is assumed that the following non-functional requirement 2′ and the following non-functional requirement 3 are designated. In addition, the implementation constraint condition is that the requirement level of the non-functional requirement related to the data recovery is below the requirement level of the non-functional requirement related to the backup. This represents that in the case where the application range of the backup is not wider than the application range of the data recovery at the operation, the requirement of the data recovery related to the operation is not satisfied.

(The non-functional requirement 2′) The item is the backup, the target is the database, and the requirement level is 1.

(The non-functional requirement 3) The item is the data recovery related to the operation, the target is the database, and the requirement level is 2 or more.

The following substitute plan is generated to the combination of the requirements in which the requirement level of the non-functional requirement 2 is 1 and the requirement level of the non-functional requirement 3 is 2.

In step S801, it is assumed that the implementation tendency in which the requirement levels of the non-functional requirement 2 and the non-functional requirement 3 are the same is identified. In this case, in step S802, the substitute plan generation unit 113 identifies the changing method for changing the requirement level of the non-functional requirement 2 to 2. When the influence is not given to the different element, the substitute plan generation unit 113 adds, to the substitute plan candidate stack, the resultant operation data to which the Change flag is given.

The architecture design assistance system 100 of the third embodiment decides the recommendation rank of the combination of the elements on the basis of the degree of the match of the implementation/operation constraint, and presents the recommendation rank to the user. With this, the user can easily grasp the combination of the elements to be adopted on a priority basis. In addition, when the combination of the elements satisfying the implementation constraint condition is not present, the architecture design assistance system 100 of the third embodiment generates the substitute plan on the basis of the history. With this, the change and the decision of the architecture design can be efficiently assisted. Since the changing of the element is identified on the basis of the history, the history can be presented as data that becomes grounds.

It should be noted that the first embodiment and the third embodiment can also be combined. For example, the architecture design assistance system 100 executes the process in step S703 after step S103, and in step S104, calculates the cost on the basis of the cost constraint condition and the implementation constraint condition.

### Fourth Embodiment

The architecture design assistance system 100 of a fourth embodiment is different from the first embodiment in that the feedback to the presented architecture is accumulated. Hereinbelow, the fourth embodiment will be described by focusing on the difference from the first embodiment.

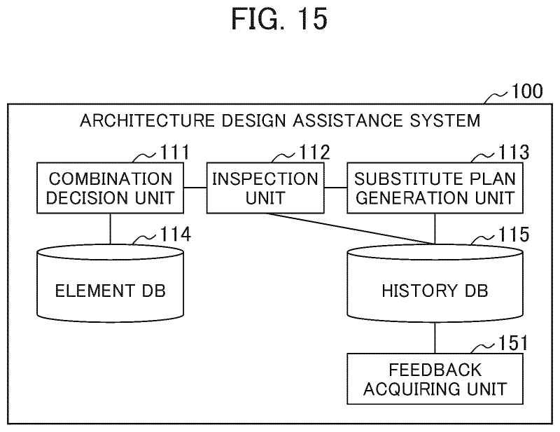

FIG. 15 is a diagram illustrating an example of the configuration of the architecture design assistance system 100 of the fourth embodiment.

The architecture design assistance system 100 of the fourth embodiment is different from the first embodiment in that a feedback acquiring unit 151 is included.

The feedback acquiring unit 151 acquires, as the feedback, the implementation result using the combination of the elements and the substitution plan that are outputted. The feedback is accumulated into the history DB 115.

The architecture design assistance system 100 of the fourth embodiment exerts the same effect as the first embodiment. Further, by accumulating the feedback to the combination of the elements and the substitute plan that are outputted, the substitute plan can be generated with higher accuracy.

It should be noted that the present invention is not limited to the embodiments described above, and includes various modification examples. For example, the above-described embodiments have been described in detail in order to facilitate the understanding of the present invention, and the present invention is not necessarily limited to those including all of the described configurations. In addition, part of the configuration of each of the embodiments can be subjected to addition, deletion, and replacement with respect to other configurations.

In addition, the above respective configurations, functions, processing units, processing means, and the like may be achieved in part or all of them by hardware, for example, by designing by an integrated circuit and the like. In addition, the present invention can be achieved also by the program code of software achieving the functions of the embodiments. In this case, a storage medium that records the program code is provided to a computer, and the processor included in the computer reads the program code stored in the storage medium. In this case, the program code itself read from the storage medium achieves the functions of the above embodiments, and the program code itself and the storage medium that stores the program code configure the present invention. As the storage medium for supplying such the program code, for example, a flexible disk, a CD-ROM, a DVD-ROM, a hard disk, an SSD (Solid State Drive), an optical disk, a magneto-optical disk, a CD-R, a magnetic tape, a non-volatile memory card, a ROM, and the like are used.

In addition, for example, the program code achieving the functions described in the present embodiments can be implemented by a program or a script language in a wide range, such as an assembler, C/C++, perl, Shell, PHP, Python, and Java.

Further, the program code of the software achieving the functions of the embodiments may be delivered via a network, the program code may be stored in the storage means, such as the hard disk and the memory of the computer, or the storage medium, such as a CD-RW and a CD-R, and the processor included in the computer may read and execute the program code stored in the storage means or the storage medium.

In the above embodiments, the control lines and the information lines that are considered to be necessary for the description are represented, and all the control lines and information lines are not necessarily represented for the product. All the configurations may be mutually connected.

1. A calculator system for assisting architecture design for an IT system,
wherein the calculator system
holds an element database that stores data in which a non-functional requirement and an element as design information for implementing the non-functional requirement are associated and a history database that stores the implementation history of the past non-functional requirement,
acquires information on the non-functional requirement implemented on the IT system that is achieved by an architecture as a base,
refers to the element database to generate a plurality of combinations of the elements each for implementing the non-functional requirement,
for each of the plurality of combinations of the elements, calculates an evaluation index used for deciding a recommendation rank,
on the basis of the evaluation index, gives a priority representing the recommendation rank of each of the plurality of combinations of the elements,
judges whether or not the combination of the elements satisfying a constraint condition is present,
when the combination of the elements satisfying the constraint condition is not present, analyzes the implementation history to identify a changing method for at least one element included in the combination of the elements,
corrects the combination of the elements on the basis of the identified changing method to generate a substitute plan, and
outputs at least one of the combination of the elements or the substitute plan sorted on the basis of the priority.

2. The calculator system according to claim 1,
wherein by analyzing the implementation history, the element in which implementation achievement is low or the element in which the requirement satisfied by the element is excessive or insufficient as compared with the past implementation history is identified as the changeable element, and
wherein the changing method for the changeable element is identified.

3. The calculator system according to claim 2,
wherein by analyzing the implementation history, the implementation tendency of the non-functional requirement is identified, and
wherein on the basis of the implementation tendency of the non-functional requirement, the changing method for the element included in the combination of the elements is identified.

4. The calculator system according to claim 2,
wherein the evaluation index is at least one of a money cost, a cost required for implementation, or a cost required for operation, and
wherein the constraint condition is a constraint condition related to at least one of the money cost, the cost required for the implementation, or the cost required for the operation.

5. The calculator system according to claim 2,
wherein the constraint condition is a constraint condition related to the implementation, and
wherein the evaluation index is a numerical value representing the degree of the match of the constraint condition.

6. The calculator system according to claim 2,
wherein the history database stores an implementation judgement history related to whether or not the past non-functional requirement can be adopted by a user,
wherein the implementation judgment history includes the element, whether or not the element can be implemented, and the type of the evaluation index as the judgement reference of the implementation of the element,
wherein the calculator system calculates a plurality of types of evaluation indexes,
wherein on the basis of the implementation judgement history, the calculator system identifies the type of the evaluation index used for the judgement of the implementation of the non-functional requirement, and
wherein on the basis of the evaluation index of the identified type, the calculator system gives the priority.

7. The calculator system according to claim 6,
wherein an implementation result using the combination of the elements and the substitute plan that are outputted is acquired as feedback, and
wherein the acquired feedback is accumulated as the implementation history or the implementation judgement history.

8. A method for assisting architecture design for an IT system executed by a calculator system,
the calculator system holding an element database storing data in which a non-functional requirement and an element as design information for implementing the non-functional requirement are associated, and a history database storing the implementation history of the past non-functional requirement,
the method for assisting the architecture design for the IT system including:
a first step in which the calculator system acquires information on the non-functional requirement implemented on the IT system achieved by an architecture as a base;
a second step in which the calculator system refers to the element database to generate a plurality of combinations of the elements each for implementing the non-functional requirement;
a third step in which for each of the plurality of combinations of the elements, the calculator system calculates an evaluation index used for deciding a recommendation rank;
a fourth step in which on the basis of the evaluation index, the calculator system gives a priority representing the recommendation rank of each of the plurality of combinations of the elements;
a fifth step in which the calculator system judges whether or not the combination of the elements satisfying a constraint condition is present;
a sixth step in which when the combination of the elements satisfying the constraint condition is not present, the calculator system analyzes the implementation history to identify a changing method for at least one element included in the combination of the elements;
a seventh step in which the calculator system corrects the combination of the elements on the basis of the identified changing method to generate a substitute plan; and
an eighth step in which the calculator system outputs at least one of the combination of the elements and the substitute plan sorted on the basis of the priority.

9. The method for assisting the architecture design for the IT system according to claim 8,
wherein the sixth step includes:
a step in which by analyzing the implementation history, the calculator system identifies, as the changeable element, the element in which implementation achievement is low or the element in which the requirement satisfied by the element is excessive or insufficient as compared with the past implementation history; and
a step in which the calculator system identifies the changing method for the changeable element.

10. The method for assisting the architecture design for the IT system according to claim 9,
wherein the sixth step includes:
a step in which by analyzing the implementation history, the calculator system identifies the implementation tendency of the non-functional requirement; and
a step in which on the basis of the implementation tendency of the non-functional requirement, the calculator system identifies the changing method for the element included in the combination of the elements.

11. The method for assisting the architecture design for the IT system according to claim 9,
wherein the evaluation index is at least one of a money cost, a cost required for implementation, or a cost required for operation, and
wherein the constraint condition is a constraint condition related to at least one of the money cost, the cost required for the implementation, or the cost required for the operation.

12. The method for assisting the architecture design for the IT system according to claim 9,
wherein the constraint condition is a constraint condition related to the implementation, and
wherein the evaluation index is a numerical value representing the degree of the match of the constraint condition.

13. The method for assisting the architecture design for the IT system according to claim 9,
wherein the history database stores an implementation judgement history related to whether or not the past non-functional requirement can be adopted by a user,
wherein the implementation judgment history includes the element, whether or not the element can be implemented, and the type of the evaluation index as the judgement reference of the implementation of the element,
wherein the third step includes:
a step in which the calculator system calculates a plurality of types of evaluation indexes, and
wherein the fourth step includes:
a step in which on the basis of the implementation judgement history, the calculator system identifies the type of the evaluation index used for the judgement of the implementation of the non-functional requirement; and
a step in which on the basis of the evaluation index of the identified type, the calculator system gives the priority.

14. The method for assisting the architecture design for the IT system according to claim 13, including:
a step in which the calculator system acquires, as feedback, an implementation result using the combination of the elements and the substitute plan that are outputted; and
a step in which the calculator system accumulates the acquired feedback as the implementation history or the implementation judgement history.
